(19) United States
(12) Patent Application Publication
(10) Pub. No.: US 2026/0016518 A1
(43) Pub. Date: Jan. 15, 2026

(54) APPARATUS FOR OUTPUTTING AMOUNT OF ENERGY CONSUMPTION OF MOUNTING ON WASTE COLLECTION VEHICLE, WASTE COLLECTION VEHICLE, METHOD FOR OUTPUTTING AMOUNT OF ENERGY CONSUMPTION OF MOUNTING ON WASTE COLLECTION VEHICLE, AND NON-TRANSITORY STORAGE MEDIUM STORING PROGRAM FOR OUTPUTTING AMOUNT OF ENERGY CONSUMPTION OF MOUNTING ON WASTE COLLECTION VEHICLE

(71) Applicant: Isuzu Motors Limited, Yokohama-shi (JP)

(72) Inventor: Keita ARATO, Fujisawa-shi (JP)

(73) Assignee: Isuzu Motors Limited, Yokohama-shi (JP)

(21) Appl. No.: 19/238,263

(22) Filed: Jun. 13, 2025

(30) Foreign Application Priority Data
Jul. 12, 2024 (JP) 2024-112557

(51) Int. Cl. G01R 22/10; B65F 1/14

(52) U.S. Cl. CPC G01R 22/10; B65F 1/14

(57) ABSTRACT

An apparatus for outputting an amount of energy consumption of a mounting on a waste collection vehicle, includes a processor configured to: acquire an operation time of the mounting on the waste collection vehicle taken by the waste collection vehicle for processing waste; and output an amount of energy consumption incurred by the waste collection vehicle for processing the waste, based on the acquired operation time and information indicating a relationship between an operation time of the mounting and an amount of energy consumption required for the mounting for processing the waste.

### CROSS REFERENCE TO RELATED APPLICATIONS

This application is based upon and claims the benefit of priority from prior Japanese Patent Application No. 2024-112557, filed Jul. 12, 2024, the entire contents of which are incorporated herein by reference.

### FIELD

The present invention relates to an apparatus for outputting an amount of energy consumption of a mounting on a waste collection vehicle, a waste collection vehicle, a method for outputting an amount of energy consumption of a mounting on a waste collection vehicle, and a non-transitory storage medium storing a program for outputting an amount of energy consumption of a mounting on a waste collection vehicle.

### BACKGROUND

A waste collection vehicle (garbage truck/dustcart) drives, for example, a hydraulic device of a waste collecting portion provided as a mounting while consuming energy (power) at the time of waste collection, etc., and causes the waste storing portion to store the waste (see Jpn. Pat. Appln. KOKAI Publication No. 2007-50996). In this manner, a waste collection vehicle consumes energy at the time of waste collection.

### SUMMARY

According to an aspect of the present invention, an apparatus for outputting an amount of energy consumption of a mounting on a waste collection vehicle, includes a processor configured to: acquire an operation time of the mounting on the waste collection vehicle taken by the waste collection vehicle for processing waste; and output an amount of energy consumption incurred by the waste collection vehicle for processing the waste, based on the acquired operation time and information indicating a relationship between an operation time of the mounting and an amount of energy consumption required for the mounting for processing the waste.

### BRIEF DESCRIPTION OF THE DRAWINGS

FIG. 1 is a schematic diagram showing a system for outputting an amount of energy consumption of waste of a waste collection vehicle according to a first embodiment.

FIG. 2 is a schematic diagram showing a waste collection vehicle (garbage truck/dustcart).

FIG. 3 is a diagram showing a processing flow of the system shown in FIG. 1.

FIG. 4 is a graph showing a relationship between an actually measured amount of energy consumption of a mounting and an amount of energy consumption of a mounting calculated (output) using a system for outputting an amount of energy consumption in a case where an oil temperature of a hydraulic device provided as a mounting on the waste collection vehicle is not taken into consideration.

FIG. 5 is a graph showing a relationship between an actually measured amount of energy consumption of a mounting and an amount of energy consumption of a mounting calculated (output) using a system for outputting an amount of energy consumption in a case where an oil temperature of a hydraulic device provided as a mounting on a waste collection vehicle is taken into consideration.

FIG. 6 is a schematic diagram showing a waste collection vehicle including an apparatus for outputting an amount of energy consumption of waste of the waste collection vehicle according to a second embodiment.

### DETAILED DESCRIPTION

Embodiments of the present invention will be explained referring to the drawings.

In the embodiments, it is assumed that the terms “waste”, “trash”, “garbage”, “rubbish”, “litter”, “refuse”, etc., used to refer to what is generally known as waste. That is, in the embodiments, “waste” intends to include “trash”, “garbage”, “rubbish”, “litter”, “refuse”, and the like.

### First Embodiment

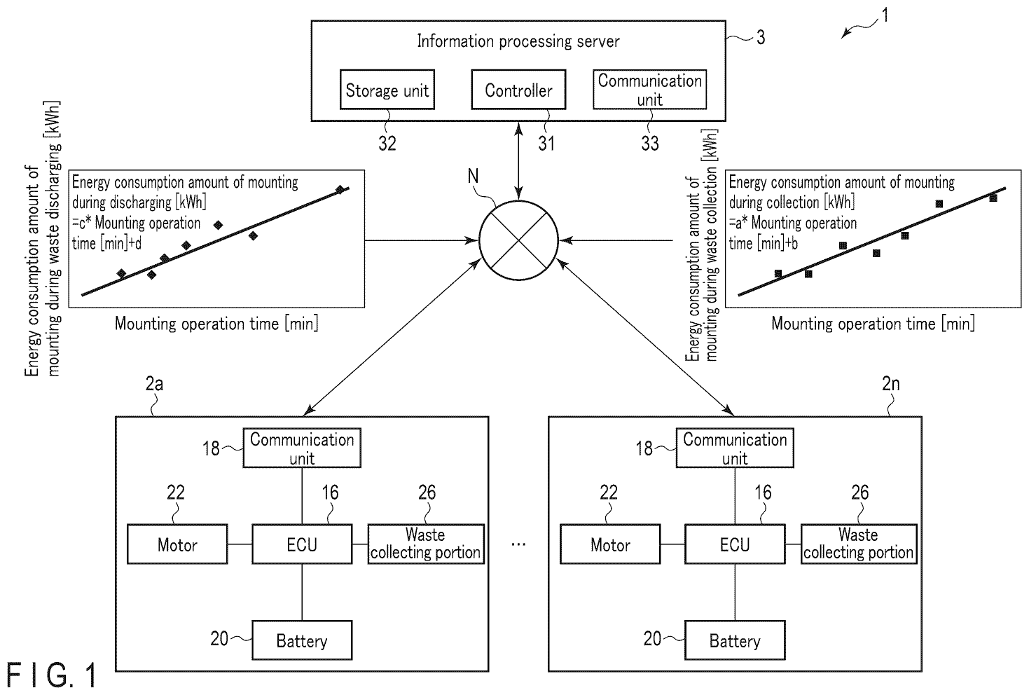

A system for outputting an amount of energy consumption of a mounting on a waste collection vehicle 2 (hereinafter mainly referred to as a “system”) 1 according to a first embodiment will be described with reference to FIGS. 1 to 5.

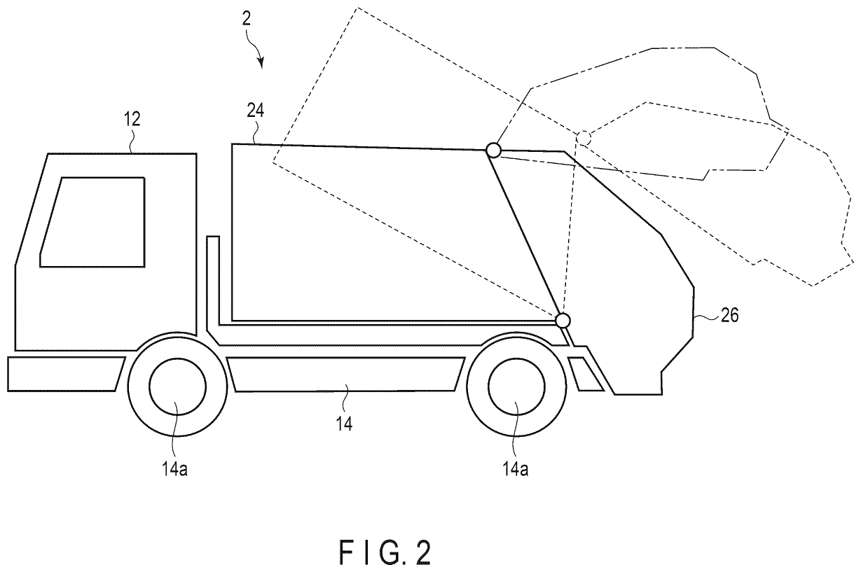

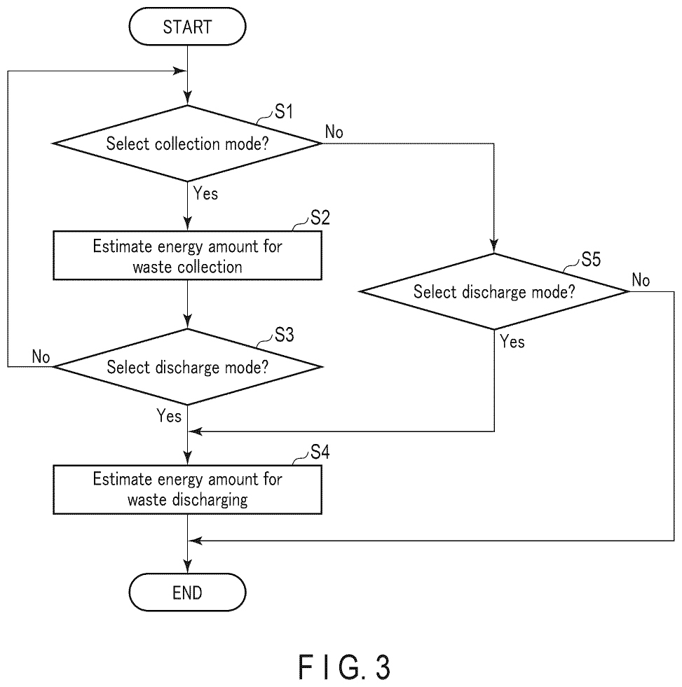

FIG. 1 is a schematic diagram of the system 1 according to the first embodiment of the present invention. The graphs of FIG. 1 show a relationship between an operation time at a time of waste collection of the waste collecting portion 26 provided as a mounting on the waste collection vehicle 2 and an amount of energy consumption at the time of waste collection, and a relationship between an operation time at a time of waste discharging of the waste collecting portion 26 provided as a mounting on the waste collection vehicle 2 and an amount of energy consumption at the time of waste discharging. FIG. 2 is a schematic diagram showing the waste collection vehicle (garbage truck/dustcart) 2. FIG. 3 shows a processing flow of the system 1.

As shown in FIG. 1, the system 1 includes n waste collection vehicles 2a to 2n (where n is an integer equal to or greater than 1) and an information processing server (apparatus) 3 for outputting an amount of energy consumption of the waste collection vehicle 2) that is communicable with the waste collection vehicles 2a to 2n via a network N.

In the description that follows, the n waste collection vehicles 2a to 2n will be simply referred to as “waste collection vehicles 2” with the individual symbols omitted if they do not need to be distinguished from one another. As a matter of course, it is preferable that the waste collection vehicles 2a to 2n be the same type of vehicles with the same mounting; however, they may be different types of vehicles with the same mounting. Furthermore, the waste collection vehicles 2a to 2n may be waste collection vehicles of different types with different mountings to which the relationships of the graphs of an amount of energy consumption of the mounting during collection and an amount of energy consumption of the mounting during discharging shown in FIG. 1 can be applied.

As shown in FIGS. 1 and 2, the waste collection vehicle 2 includes, in addition to the cab 12 and the chassis 14, an electronic control unit (ECU) 16, a communication unit 18, a battery 20, a motor 22, a waste storing portion 24, and a waste collecting portion 26.

Permissible examples of the waste collection vehicle 2 according to the present embodiment include an electric vehicle (EV) and an engine vehicle such as a diesel engine vehicle, a hybrid electric vehicle (HEV), a plug-in hybrid electric vehicle (PHEV), and a fuel cell electric vehicle (FCEV). It is assumed herein that the waste collection vehicle 2 is an EV, and the ECU 16, the communication unit 18, the battery 20, the motor 22, the waste storing portion 24, and the waste collecting portion 26 are disposed in the chassis 14. Of these elements, the waste storing portion 24 and the waste collecting portion 26 are disposed as a mounting on the truck.

The ECU 16 is a computer of the waste collection vehicle 2, and includes a control unit configured to control each unit of the waste collection vehicle 2. The ECU 16 is configured of, for example, electronic circuitry such as one or more processors, such as CPUs. The ECU (processor) 16 controls the entire operation of the waste collection vehicle 2 in accordance with a program stored in a storage unit included in the ECU 16. The ECU (processor) 16 executes various programs stored in the storage unit of the ECU 16 to realize corresponding functions and execute various operations.

The waste collection vehicle 2 may include either a single ECU 16 or a plurality of ECUs 16, for example, an

ECU for controlling elements related to the vehicle moving and an ECU for controlling the mounting such as the waste collecting portion 26. For ease of explanation, a case is assumed, as an example, where a single ECU 16 is provided in each waste collection vehicle 2. In the case where the plurality of ECUs 16 are divided into the one for controlling the elements related to the vehicle moving and the one for controlling the mounting such as the waste collecting portion 26, the waste collection vehicle 2 is controlled in a similar manner to the case of the single ECU 16.

The communication unit 18 transmits and receives various information signals related to the waste collection vehicle 2 to and from a server or computer 3 of the system 1 via the network N.

The battery 20 supplies, to the mounting such as the ECU 16, the communication unit 18, the motor 22, the waste collecting portion 26, etc., a suitable amount of power to be controlled by the ECU 16.

The motor 22 is used as a drive source for driving the wheels 14a of the waste collection vehicle 2 by power from the battery 20.

The waste storing portion 24 is, for example, provided between the cab 12 and the waste collecting portion 26, and is formed as a container for storing waste.

The waste collecting portion 26 operates a hydraulic device of the waste collecting portion 26 by power from the battery 20, and causes the waste storing portion 24 to store waste. Also, depending on the type of the waste collecting portion 26 of the waste collection vehicle 2, the waste collecting portion 26 is capable of operating the hydraulic device of the waste collecting portion 26 by power from the battery 20, to cause the waste to be discharged to the outside of the waste collection vehicle 2 from the waste storing portion 24.

For ease of explanation, it is assumed herein that the waste collecting portion 26, provided as a mounting on the waste collection vehicle 2, can be driven by switching between a collection mode of storing waste into the waste storing portion 24 and a discharge mode of discharging waste stored in the waste storing portion 24 to the outside. The waste collection vehicle 2 includes a switch of operating the hydraulic device of the waste collecting portion 26 in the collection mode and a switch of operating the hydraulic device of the waste collecting portion 26 in the discharge mode. The ECU 16 performs control in such a manner that the operations of the collection mode and the discharge mode are not simultaneously performed even if the switch for the collection mode and the switch for the discharge mode are simultaneously pressed down.

It is assumed that, in the collection mode, the mounting (the hydraulic device of the waste collecting portion 26) on the waste collection vehicle 2 is driven to collect waste at one or more spots.

As a mechanism by which the waste collecting portion 26 stores waste in the waste storing portion 24 in the collection mode, any one of the known methods such as a rotating type (rotating-plate type), a pressing type (pressure-plate type), a rotary type that uses a drum, or the like may be used. If the relationship in the graph of the amount of energy consumption during waste collection shown in FIG. 1 differs according to these types, graphs corresponding to the respective types should be prepared. In the present embodiment, it is assumed that the rotary type is used as a mechanism for the waste collecting portion 26 in the collection mode.

In the present embodiment, it is assumed that, in the discharge mode, the mounting (e.g., the hydraulic device of the waste collecting portion 26) on the waste collection vehicle 2 is driven to sequentially discharge waste stored in the waste storing portion 24 to the outside of the waste collection vehicle 2 at, for example, a waste incineration plant, etc.

As a mechanism by which the waste is discharged from the waste storing portion 24 in the discharge mode, any one of the known methods such as the rotary type that inversely rotates a drum, a pushing type that moves a pusher plate (not illustrated), and a dump type that lifts the waste storing portion 24 using, for example, a hoist mechanism (not illustrated) may be used. In the present embodiment, it is assumed that, in the discharge mode, a rotary-type mechanism, which drives the hydraulic device of the waste collecting portion 26, is used.

The operation time of the waste collecting portion 26 in each of the collection mode and the discharge mode is a period of time during which the hydraulic device of the waste collecting portion 26 has been operated using power from the battery 20 in response to a pressing-down of the switch of the waste collecting portion 26 by a waste collecting worker.

The waste collection vehicle 2 consumes energy (power) from the battery 20 at the time of moving to one or more spots for waste collection, at the time of moving to a waste incineration plant, etc. for waste discharging after collection of the waste, and at the time of operation (collection and discharging) of the waste collecting portion 26 provided as a mounting.

FIG. 1 is a block diagram schematically showing a configuration example of an information processing server 3 according to the present embodiment.

The server 3 is a computer including a controller 31, a storage unit 32, and a communication unit 33. The controller 31, the storage unit 32, and the communication unit 33 are mutually connected via a bus line.

The controller 31 controls the entire operation of the information processing server 3 in accordance with programs stored in the storage unit 32. The controller 31 is configured of, for example, electronic circuitry such as one or more processors. It is assumed, for example, that the controller 31 is a CPU. The controller 31 executes various programs stored in the storage unit 32 to realize corresponding functions and execute various operations.

The storage unit 32 is configured of a main storage and an auxiliary storage. The main storage is configured of, for example, a volatile memory that provides a work area for a processor. The main storage is configured of, for example, a random-access memory (RAM), etc. The auxiliary storage is, for example, a non-transitory storage medium, and is configured of, for example, a nonvolatile memory configured to store a variety of information and programs for operation of the information processing server 3. The auxiliary storage is configured of, for example, a hard disk drive (HDD) or a solid-state drive (SSD). The storage unit 32 causes the controller 31 to store programs for realizing various functions. The storage unit 32 further stores information shown in the graph of FIG. 1, which is provided via, for example, the network N. Note that, in the present embodiment, the storage unit 32 is configured, for example, to store an energy consumption amount outputting program of the waste collection vehicle 2, which is executed by the controller 31. It is preferable that the storage unit 32 be configured to also store an output of an estimated amount of energy consumption, to be discussed below, for each waste collection vehicle 2.

FIG. 1 shows a graph in which the lateral axis represents an operation time of the hydraulic device of the waste collecting portion 26 provided as a mounting, and the vertical axis represents an amount of energy consumption of the mounting during waste collection, and a graph in which the lateral axis represents an operation time of the waste collecting portion 26 provided as a mounting, and the vertical axis represents an amount of energy consumption of the mounting at the time of waste discharging. The data related to the amount of energy consumption of the mounting during collection shown in FIG. 1 is an example of a relationship obtained by actually measuring an operation time of the mounting and an amount of energy consumption at the time of collecting household waste at a plurality of spots on a route using the hydraulic device of the waste collecting portion 26 provided as a mounting on one or more waste collection vehicles 2. Also, the data related to the amount of energy consumption of the mounting during discharging is an example of a relationship between an operation time of the mounting and an amount of energy consumption at the time of collecting household waste at a plurality of spots on a route using a hydraulic device of the waste collecting portion 26 provided as a mounting on one or more waste collection vehicles 2, and then discharging the waste. Herein, a linear approximation line is set, as an example, for each of the data related to the amount of energy consumption of the mounting during collection and the data related to the amount of energy consumption of the mounting during discharging. It is assumed herein that the server (apparatus) 3 for outputting an amount of energy consumption of the mounting on the waste collection vehicle 2 makes an estimated output of the amount of energy consumption relative to the actual operation time based on the set approximation lines.

The relationships shown in the two graphs of FIG. 1 are shown merely as an example, and may change according to the type, etc. of waste. The household waste can be sorted into, for example, plastics, PET bottles, metals, paper, and others, although such sorting differs according to the local government. Thus, the operation time of the mounting at the time of collection by the waste collection vehicle 2 changes according to the types of waste into which the waste is sorted.

It is preferable that the data related to the amount of energy consumption of the mounting during collection and the data related to the amount of energy consumption of the mounting during discharging as shown in FIG. 1 be acquired in advance by the server 3 via the network N and stored in the storage unit 32. Alternatively, it is also preferable that data be stored in a server separate from the server 3 in such a manner that the server 3 acquires the data via the network N at the time of outputting an amount of energy consumption. For example, after data is acquired by the server 3 and temporarily stored therein, the data may be stored in, for example, the storage unit 32 of the server 3.

The communication unit 33 is configured of one or more communication interfaces capable of performing communications compliant with a given wireless communication standard. The communication unit 33 includes one or more communication interfaces that enable communications between the information processing server 3 and the waste collection vehicle 2 via the network N, as described above.

A hardware configuration of the information processing server 3 is not limited to the above-described one. The above-described constituent elements of the information processing server 3 can be suitably omitted and/or altered;

furthermore, new constituent elements may be suitably added.

The system 1 is what is known as a client-server system. The system 1 is realized through mutual communication between the server 3 and the ECU 16 of each of n waste collection vehicles 2, which are clients, via the network N and the communication units 18 and 33. Note that the network N is realized by a network such as the Internet, a mobile telephone network, or a local area network (LAN), or a network that is a combination of them.

An energy consumption amount outputting process of the waste collection vehicle 2 as realized by the controller 31 of the information processing server 3 will be described with reference to FIG. 3. Each of the processes being realized by the controller 31 may also be said to be realized by a computer including a processor.

For example, the worker of the waste collection vehicle 2 presses down a switch for the collection mode at a first waste collection spot, with a suitable amount of waste put in the waste collecting portion 26, and drives the hydraulic device of the waste collecting portion 26.

The worker turns the switch for the collection mode to OFF to stop the operation of the hydraulic device of the waste collecting portion 26 at the point in time when the waste is stored in the waste storing portion 24 by an operation of the waste collecting portion 26. The ECU 16 transmits, to the information processing server 3 via the communication unit 18, information on a start time (a point in time of starting) and a stop time (a point in time of stopping) of the operation of the hydraulic device of the waste collecting portion 26 of the waste collection vehicle 2 in the collection mode, or information on the actual operation time of the hydraulic device of the waste collecting portion 26 based on the difference between the start time (point in time of starting) and the stop time (point in time of stopping). That is, the server 3 acquires an operation time of the mounting on the waste collection vehicle 2 taken by the waste collection vehicle 2 to process the waste. It is assumed herein that the ECU 16 transmits the latter, namely, the information on the actual operation time of the hydraulic device of the waste collecting portion 26. The server 3 determines whether the information from the waste collection vehicle 2 is an operation in the collection mode (step S1).

If the server 3 has determined that the collection mode has been selected (executed) by the waste collection vehicle 2 (step S1—Yes), the server (apparatus) 3 for outputting an amount of energy consumption of the mounting on the waste collection vehicle 2) reads a relationship shown in the above-described graph from the storage unit 32, or acquires the relationship shown in the above-described graph via the network N in response to an input of the actual operation time of the mounting at the time of waste collection by the waste collection vehicle 2, and outputs an estimated amount of energy consumption corresponding to the actual operation time of the mounting at the time of waste collection by the waste collection vehicle 2. Thus, the server 3 outputs an amount of energy consumption incurred by the waste collection vehicle 2 to process the waste, based on the acquired operation time and the information indicating the relationship between the operation time of the mounting and the amount of energy consumption required for the mounting to process the waste. That is, the server 3 outputs an estimated amount of energy consumption corresponding to the actual operation time of the hydraulic device of the waste collecting portion 26, provided as a mounting, based on an input of information related to the actual operation time of the hydraulic device of the waste collecting portion 26, provided as the mounting, from the ECU 16 of the waste collection vehicle 2 (step S2). This output is stored in, for example, the storage unit 32 of the server 3.

Note that, if the ECU 16 has transmitted, to the server 3, the information on the start time (point in time of starting) and the stop time (point in time of stopping) of the operation of the hydraulic device of the waste collecting portion 26 of the waste collection vehicle 2 in the collection mode, it can be construed that the actual operation time of the hydraulic device of the waste collecting portion 26 has been input to the controller 31 of the server 3.

Also, the worker of the waste collection vehicle 2 presses down a switch for the collection mode at a second waste collection spot, with a suitable amount of waste put in the waste collecting portion 26, and drives the hydraulic device of the waste collecting portion 26. The server 3 determines whether the mode that is executed next by the waste collection vehicle 2 is the discharge mode (step S3). If it is determined at step S3 that the discharge mode has not been selected (step S3—No) the processing returns to step S1. Thus, the server 3 outputs an estimated amount of energy consumption of the hydraulic device of the waste collecting portion 26 in the collection mode at each waste collection spot until the switch for the discharge mode is turned to ON.

Accordingly, the apparatus for outputting an amount of energy consumption of the mounting on the waste collection vehicle 2 is, for example, the server 3, which acquires an operation time of the mounting on the waste collection vehicle 2 taken by the waste collection vehicle 2 to process (e.g., collect) the waste, and outputs an amount of energy consumption incurred by the waste collection vehicle 2 to process the waste, based on the acquired operation time and the information indicating the relationship between the operation time of the mounting and the amount of energy consumption required for the mounting to process the waste. Also, the method for outputting an amount of energy consumption of the mounting on the waste collection vehicle 2 includes acquiring an operation time of the mounting on the waste collection vehicle 2 taken by the waste collection vehicle 2 to process (e.g., collect) the waste, and outputting an amount of energy consumption incurred by the waste collection vehicle 2 to process the waste, based on the acquired operation time and the information indicating the relationship between the operation time of the mounting and the amount of energy consumption required for the mounting to process the waste. At this time, the server (apparatus) 3 for outputting an amount of energy consumption of the mounting on the waste collection vehicle 2) reads the above-described relationship from the storage unit 32 or acquires the above-described relationship via the network N in response to an input of the actual operation time of the mounting at the time of waste processing (e.g., collection) by the waste collection vehicle 2, and outputs an estimated amount of energy consumption corresponding to the actual operation time of the mounting at the time of waste processing (e.g., collection) by the waste collection vehicle 2. More specifically, a program for outputting an amount of energy consumption of a mounting on the waste collection vehicle 2 causes a controller (computer) 31 of the server 3 to read the above-described relationship from the storage unit 32 of the server 3 or to acquire the above-described relationship via the network N, and to output an estimated amount of energy consumption of the mounting corresponding to an actual operation time of the mounting in response to an input of the actual operation time of the mounting at the time of waste processing (e.g., collection).

Note that, at every execution of step S2, the server 3 outputs not only an individual amount of energy consumption of the mounting at each waste collection spot of the waste collection vehicle 2 but also an accumulated amount of energy consumption. These outputs are stored in, for example, the storage unit 32 of the server 3. The output of the individual amount of energy consumption and the output of the accumulated amount of energy consumption can be read by a user of the server 3.

After waste is collected at, for example, all the waste collection spots that had been scheduled, the worker of the waste collection vehicle 2 presses down the switch for the discharge mode at, for example, a location where the waste is discharged at a waste incineration plant to drive the hydraulic device of the waste collecting portion 26. Upon determining that all the waste stored in the waste storing portion 24 has been discharged to the outside of the waste collection vehicle 2 through the waste collecting portion 26, the worker turns the switch for the discharge mode to OFF to stop operation of the hydraulic device of the waste collecting portion 26. The ECU 16 transmits, to the information processing server 3 via the communication unit 18, information on a start time (a point in time of starting) and a stop time (a point in time of stopping) of the operation of the hydraulic device of the waste collecting portion 26 of the waste collection vehicle 2 in the discharge mode, or information on the actual operation time of the hydraulic device of the waste collecting portion 26 based on the difference between the start time (point in time of starting) and the stop time (point in time of stopping). That is, the server 3 acquires an operation time of the mounting on the waste collection vehicle 2 taken by the waste collection vehicle 2 to process the waste. It is assumed herein that the ECU 16 transmits the latter, namely, the information on the actual operation time of the hydraulic device of the waste collecting portion 26. The server 3 determines whether the information from the waste collection vehicle 2 is an operation in the discharge mode (step S3).

If the server 3 has determined that the discharge mode has been selected (executed) by the waste collection vehicle 2 (step S3—Yes), the server (apparatus) 3 for outputting the amount of energy consumption of the mounting on the waste collection vehicle 2 reads the relationship shown in the above-described graph from the storage unit 32 or acquires the relationship shown in the above-described graph via the network N in response to an input of an actual operation time of the mounting at the time of waste discharging from the waste collection vehicle 2, and outputs an estimated amount of energy consumption corresponding to the actual operation time of the mounting at the time of waste discharging from the waste collection vehicle 2. Thus, the server 3 outputs an amount of energy consumption incurred by the waste collection vehicle 2 to process the waste, based on the acquired operation time and the information indicating the relationship between the operation time of the mounting and the amount of energy consumption required for the mounting to process the waste. That is, the server 3 outputs an estimated amount of energy consumption corresponding to the actual operation time of the hydraulic device of the waste collecting portion 26, provided as a mounting, based on an input of information related to the actual operation time of the hydraulic device of the waste collecting portion 26, provided as the mounting, from the ECU 16 of the waste collection vehicle 2 (step S4). This output is stored in, for example, the storage unit 32 of the server 3. The output of the amount of energy consumption at the time of waste discharging and the output of the accumulated amount of energy consumption during a series of procedures from waste collection to waste discharging can be read by a user of the server 3.

Note that, if the ECU 16 has transmitted, to the server 3, the information on the start time (point in time of starting) and the stop time (point in time of stopping) of the operation of the hydraulic device of the waste collecting portion 26 of the waste collection vehicle 2 in the discharge mode, it can be construed that the actual operation time of the hydraulic device of the waste collecting portion 26 has been input to the controller 31 of the server 3.

Accordingly, the server (apparatus) 3 for outputting an amount of energy consumption of the mounting on the waste collection vehicle 2 acquires an operation time of the mounting on the waste collection vehicle 2 taken by the waste collection vehicle 2 to process (e.g., discharge) the waste, and outputs an amount of energy consumption incurred by the waste collection vehicle 2 to process the waste, based on the acquired operation time and the information indicating the relationship between the operation time of the mounting and the amount of energy consumption required for the mounting to process the waste. Also, the method for outputting an amount of energy consumption of a mounting on the waste collection vehicle 2 includes acquiring an operation time of the mounting on the waste collection vehicle 2 taken by the waste collection vehicle 2 to process (e.g., discharge) the waste, and outputting an amount of energy consumption incurred by the waste collection vehicle 2 to process the waste, based on the acquired operation time and the information indicating the relationship between the operation time of the mounting and the amount of energy consumption required for the mounting to process the waste. At this time, the server 3 (the apparatus for outputting an amount of energy consumption of the mounting on the waste collection vehicle 2) reads the above-described relationship from the storage unit 32 or acquires the above-described relationship via the network N in response to an input of an actual operation time of the mounting at the time of waste processing (e.g., discharging) from the waste collection vehicle 2, and outputs an estimated amount of energy consumption corresponding to the actual operation time of the mounting at the time of waste processing (e.g., discharging) from the waste collection vehicle 2. More specifically, a program for outputting an amount of energy consumption of a mounting on the waste collection vehicle 2 causes a controller (computer) 31 of the server 3 to read the above-described relationship from the storage unit 32 of the server 3 or to acquire the above-described relationship via the network N, and to output an estimated amount of energy consumption corresponding to an actual operation time of the mounting in response to an input of the actual operation time of the mounting at the time of waste discharging.

Upon determining, at step S1, that the collection mode of the waste collection vehicle 2 has not been selected (step S1—No) after estimating the amount of energy consumption at the time of waste discharging, the server 3 determines whether or not the discharge mode has been selected (step S5). Upon determining that the discharge mode has been selected (step S5—Yes), the server 3 performs processing at step S4.

Upon determining, at step S5, that the discharge mode has not been selected (step S5—No), the server 3 ends the process of outputting the amount of energy consumption of the hydraulic device of the waste collecting portion 26 of the waste collection vehicle 2.

Note that the flow of processing by the controller 31 of the server 3 shown in FIG. 3 is merely an example, and other processing flows are permitted. For example, the controller 31 of the server 3 may be configured to acquire signals for turning the switches for the collection mode and the discharge mode of each waste collection vehicle 2 to ON and OFF via the communication unit 18 controlled by the ECU 16 of each waste collection vehicle 2, determine an actual operation time of the hydraulic device of the waste collecting portion 26 in each of the collection mode and the discharge mode of the waste collection vehicle 2, and output an estimated amount of energy corresponding to each operation time based on the relationships shown in the graphs of FIG. 1.

Accordingly, the server 3 is capable of estimating, from the actual operation time of the mounting on the waste collection vehicle 2, an amount of energy consumption at the time of waste processing (collection and/or discharging) using the waste collection vehicle 2. That is, the server 3 is capable of outputting an amount of energy consumption of the mounting on the waste collection vehicle 2 at the time of waste processing.

The server 3 is capable of collecting information on the operation time of the mounting on the waste collection vehicle 2, and outputting an amount of energy consumption of the mounting. By outputting the amount of energy consumption at the time of moving of the waste collection vehicle 2, it is possible to predict a total amount of energy consumption, power efficiency, and the like of the waste collection vehicle 2 including the mounting. It is also possible for a manufacturer of the waste collection vehicle 2, which is a user of the server 3, to provide, based on information on the server 3, a total amount of energy consumption of the waste collection vehicle 2 to the user of the waste collection vehicle 2, and to make a high-precision proposal such as a proposal for the number of battery packs required for the waste collection vehicle 2, at the time of supporting introduction of the waste collection vehicle 2. For example, it is possible for the manufacturer of the waste collection vehicle 2 to propose high-precision and high-efficiency charging management and optimization of the waste collection path at the time of performing operation support of the user of the waste collection vehicle 2.

According to the present embodiment, it is possible to provide an apparatus (server) 3 for outputting an amount of energy consumption of a mounting on a waste collection vehicle 2, a method for outputting an amount of energy consumption of a mounting on a waste collection vehicle 2, and a non-transitory storage medium storing a program for outputting an amount of energy consumption of a mounting on a waste collection vehicle 2, whereby an amount of energy consumption of a mounting on a waste collection vehicle can be output at a lower cost.

In the present embodiment, an example has been described in which the server 3 acquires an actual operation time of the mounting via the communication unit 18 from the ECU 16 online. The server 3 may be configured to acquire data offline from a data measuring device equipped in the waste collection vehicle 2.

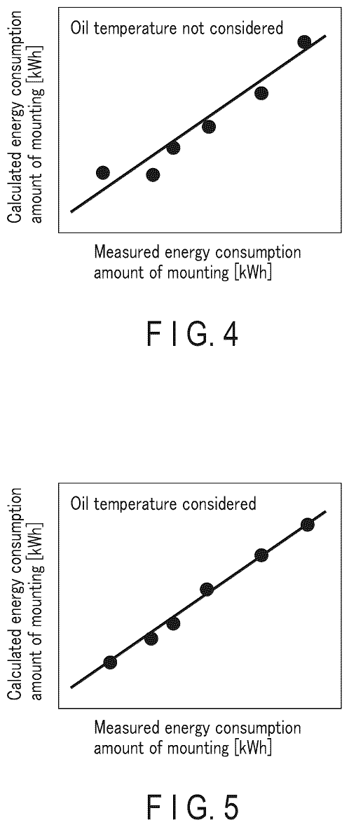

In FIGS. 4 and 5, the lateral axis represents an actually measured amount of energy consumption of the mounting, and the vertical axis represents an amount of energy consumption of the mounting calculated by the server 3 using the relationship in the graph of FIG. 1 showing the amount of energy consumption of the mounting during collection. The lateral axes of FIGS. 4 and 5 are identical to each other, even though the actual numerical ranges are not shown. Also, the vertical axes of FIGS. 4 and 5 are identical to each other, even though the actual numerical ranges are not shown.

The oil temperature of the hydraulic device of the waste collecting portion 26 is set within an optimum temperature range. In the case where the oil temperature of the hydraulic device of the waste collecting portion 26 is not taken into consideration, as shown in FIG. 4, the error of the calculated amount of energy consumption of the mounting from the actually measured amount of energy consumption of the mounting increases, compared to the case where the oil temperature of the hydraulic device of the waste collecting portion 26 is taken into consideration, as shown in FIG. 5. By using data that takes into consideration the oil temperature as the amount of energy consumption of the mounting during waste collection/discharging as shown in FIG. 1, it is possible to output an amount of energy consumption of the mounting from the operation time of the mounting with higher precision.

The amount of energy consumption of the mounting output by the server 3 may take into consideration the effects of an increase/decrease of the friction of a hydraulic system according to a change in oil temperature of the hydraulic device of the waste collecting portion 26 and a compression operation (“inching”) of the waste storing portion 24 in a full-waste state.

In the present embodiment, an example has been described in which a rotary-type mechanism, which drives the hydraulic device of the waste collecting portion 26, is used as the mounting for discharging the waste. In the case of using the pushing type, the waste collecting portion 26 is rotated relative to the waste storing portion 24 to open the waste storing portion 24 and discharge waste with the pusher plate, as shown by the two-dot chain line in FIG. 2. In the case of using the dump type, the waste storing portion 24 is tilted using the hoist mechanism, and the waste collecting portion 26 is rotated relative to the waste storing portion 24 to open the waste storing portion 24 and discharge the waste therefrom. If the relationship in the graph of the amount of energy consumption during waste discharging shown in FIG. 1 differs according to a difference in these types, graphs of the relationships corresponding to the respective types should be prepared.

Note that, in the case of using, for example, the dump type, the waste storing portion 24 and the waste collecting portion 26 of the waste collection vehicle 2 move between the position indicated by the solid line and the position indicated by the dashed line in FIG. 2. The fluctuation of the amount of energy consumption of the mounting at the time of waste discharging from the waste collection vehicle 2 is not great, compared to the amount of energy consumption at the time of waste collection into the waste collection vehicle 2. At this time, the amount of energy consumption may be substantially constant. Thus, the amount of energy consumption during waste discharging shown in FIG. 1 may be set to a predetermined amount for every movement, regardless of time. Accordingly, the server 3 may be configured to give an amount of energy consumption of the mounting at the time of waste discharging from the waste collection vehicle 2 a constant value, without using the relationship in the graph shown in FIG. 1.

In the present embodiment, an example has been described in which the waste collection vehicle 2 is an EV and derives its energy from the power of the battery 20. In the case where an engine vehicle such as a diesel vehicle, a hybrid electric vehicle (HEV), a plug-in hybrid electric vehicle (PHEV), or a fuel cell electric vehicle (FCEV) is used as the above-described waste collection vehicle 2, in place of an EV, the power for driving the hydraulic device of the waste collecting portion 26 is obtained by a system known as a power take-off (PTO), which mainly employs an output of an engine at the time of stopping of the waste collection vehicle 2. In such a case, light oil is used as an energy source for the engine vehicle. By obtaining the graph of the relationship between the operation time of the PTO system and the amount of usage of light oil as an energy source, the server is capable of outputting an amount of energy consumption (amount of usage of fuel) corresponding to the actual operation time of the PTO system. Accordingly, in this case, too, it is possible to provide an apparatus (server) 3 for outputting an amount of energy consumption of a mounting on a waste collection vehicle 2, a method for outputting an amount of energy consumption of a mounting on a waste collection vehicle 2, and a non-transitory storage medium storing a program for outputting an amount of energy consumption of a mounting on a waste collection vehicle, whereby an amount of energy consumption of a mounting on the waste collection vehicle 2 is output at a lower cost.

### Second Embodiment

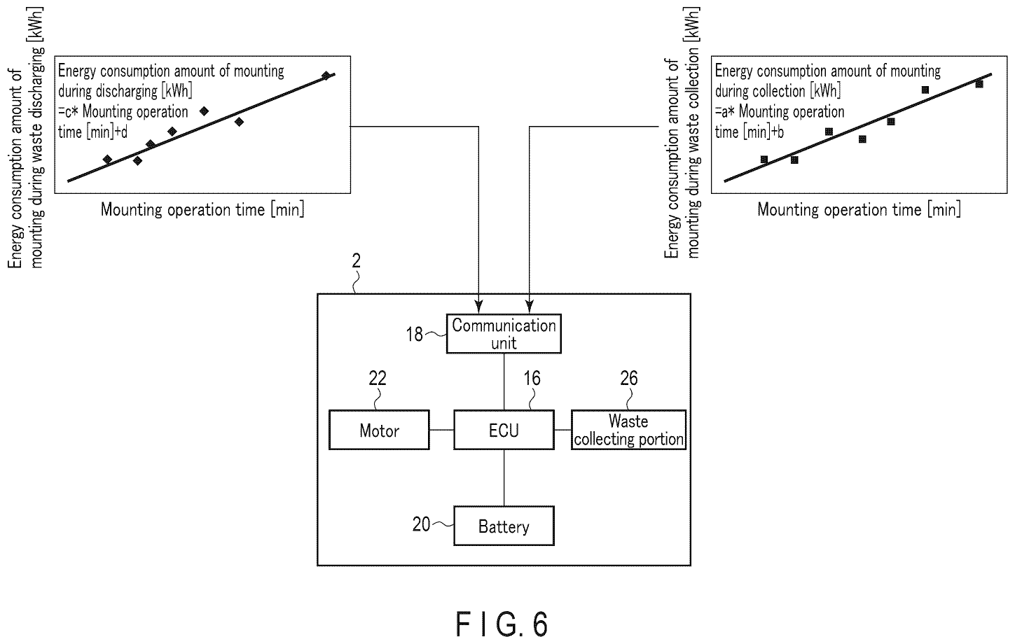

FIG. 6 is a schematic diagram showing a waste collection vehicle 2 including an apparatus (ECU) 16 for outputting an amount of energy consumption of a mounting on a waste collection vehicle 2 according to a second embodiment.

In the first embodiment, an example has been described in which the server 3, which functions as an apparatus for outputting an amount of energy consumption of a mounting on the waste collection vehicle 2, outputs an amount of energy consumption of the mounting on each waste collection vehicle 2 during a series of procedures from waste collection to waste discharging.

The ECU 16 of the waste collection vehicle 2 shown in FIG. 6 is used as an apparatus for outputting an amount of energy consumption of the mounting on the waste collection vehicle 2. Thus, the ECU 16 of the waste collection vehicle 2 shown in FIG. 6 may be configured to execute a program that follows the flow shown in FIG. 3. In this case, at the time of calculating an amount of energy consumption of the mounting, the ECU 16 may be configured to cause the storage unit of the ECU 16 to store a relationship between the operation time of the waste collecting portion 26 provided as a mounting as shown in the graph of FIG. 1 and read and output the stored relationship from the storage unit, or to output an estimated amount of energy consumption of the mounting through acquisition via the communication unit 18.

In this case, an apparatus 16 for outputting an amount of energy consumption of the waste collection vehicle 2 is provided in, for example, the storage unit of the ECU 16 and/or a program for outputting an amount of energy consumption of the waste collection vehicle 2 is stored in, for example, the storage unit of the ECU 16 so as to be executed by the controller of the ECU 16.

According to the present embodiment, it is possible to provide an apparatus (ECU) 16 for outputting an amount of energy consumption of a mounting on the waste collection vehicle 2, a waste collection vehicle 2, a method for outputting an amount of energy consumption of a mounting on a waste collection vehicle 2, and a non-transitory storage medium storing a program for outputting an amount of energy consumption of a mounting on a waste collection vehicle 2, whereby an amount of energy consumption of a mounting on a waste collection vehicle 2 can be output at a lower cost.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An apparatus for outputting an amount of energy consumption of a mounting on a waste collection vehicle, the apparatus comprising a processor configured to:
acquire an operation time of the mounting on the waste collection vehicle taken by the waste collection vehicle for processing waste; and
output an amount of energy consumption incurred by the waste collection vehicle for processing the waste, based on the acquired operation time and information indicating a relationship between an operation time of the mounting and an amount of energy consumption required for the mounting for processing the waste.

2. The apparatus according to claim 1, wherein the processor is configured to:
acquire an operation time of the mounting taken by the waste collection vehicle for collecting the waste as the waste processing; and
output an amount of energy consumption incurred by the waste collection vehicle for collecting the waste as the waste processing, based on the acquired operation time and information indicating a relationship between the operation time of the mounting and an amount of energy consumption required for the mounting to collect the waste.

3. The apparatus according to claim 1, wherein the processor is configured to:
acquire an operation time of the mounting taken by the waste collection vehicle for discharging the waste as the waste processing; and
output an amount of energy consumption incurred by the waste collection vehicle for discharging the waste as the waste processing, based on the acquired operation time and information indicating a relationship between the operation time of the mounting and an amount of energy consumption required for the mounting to discharge the waste.

4. The apparatus according to claim 1, further comprising a storage unit configured to store the relationship, wherein
the processor is configured to read the relationship from the storage unit in response to an input of the operation time, and output the amount of energy consumption corresponding to the operation time.

5. A waste collection vehicle comprising the apparatus according to claim 1.

6. A method for outputting an amount of energy consumption of a mounting on the waste collection vehicle, comprising:
acquiring an operation time of the mounting on the waste collection vehicle taken by the waste collection vehicle for processing waste; and
outputting an amount of energy consumption incurred by the waste collection vehicle for processing the waste, based on the acquired operation time and information indicating a relationship between an operation time of the mounting and an amount of energy consumption required for the mounting for processing the waste.

7. The method according to claim 6, wherein:
the acquiring of the operation time of the mounting on the waste collection vehicle includes acquiring an operation time of the mounting taken by the waste collection vehicle for collecting the waste as the waste processing, and
the outputting of the amount of energy consumption includes outputting an amount of energy consumption incurred by the waste collection vehicle for collecting the waste as the waste processing.

8. A non-transitory storage medium storing a program for outputting an amount of energy consumption of a mounting on a waste collection vehicle, the program causing a computer to:
acquire an operation time of the mounting on the waste collection vehicle taken by the waste collection vehicle for processing waste; and
output an amount of energy consumption incurred by the waste collection vehicle for processing the waste, based on the acquired operation time and information indicating a relationship between an operation time of the mounting and an amount of energy consumption required for the mounting for processing the waste.

9. The non-transitory storage medium according to claim 8, wherein
the acquiring of the operation time of the mounting on the waste collection vehicle includes acquiring an operation time of the mounting taken by the waste collection vehicle for collecting the waste, and
the outputting of the amount of energy consumption includes outputting an amount of energy consumption incurred by the waste collection vehicle for collecting the waste.
